(19) United States
(12) Patent Application Publication
(10) Pub. No.: US 2026/0164608 A1
(43) Pub. Date: Jun. 11, 2026

(54) COOLING PUMP MODULE AND AUXILIARY CONNECTING DEVICE THEREOF

(71) Applicant: LITE-ON TECHNOLOGY CORPORATION, Taipei (TW)

(72) Inventors: Duan-You SYU, Taipei (TW); Yu-Hsi LIN, Taipei (TW); Shu-Hua MAU, Taipei (TW); Wen-Chi CHEN, Taipei (TW)

(21) Appl. No.: 19/354,088

(22) Filed: Oct. 9, 2025

Related U.S. Application Data
(60) Provisional application No. 63/728,210, filed on Dec. 5, 2024.

(30) Foreign Application Priority Data
Apr. 22, 2025 (CN) 202510509200.8

(51) Int. Cl. H05K 7/20

(52) U.S. Cl. CPC H05K 7/20772

(57) ABSTRACT

According to one aspect of the present invention, an auxiliary connecting device is provided. The auxiliary connecting device includes a tray, a base, and a guide rod. The tray has a first bearing fixed thereon. The base is slidably disposed on the tray. The base has a second bearing fixed thereon. The guide rod is rotatably disposed and passes through the second bearing. When the base slides relative to the tray, the guide rod moves toward the first bearing. When the guide rod moves close to the first bearing, the guide rod is rotatable to engage with the first bearing. When the guide rod rotates in the first bearing, the guide rod pushes against the second bearing to apply a force to the base.

This application claims the benefit of the U.S. provisional application Ser. No. 63/728,210, filed Dec. 5, 2024, and CN application Serial No. 202510509200.8, filed Apr. 22, 2025, the disclosures of which are incorporated by reference herein in its entirety.

### TECHNICAL FIELD

The present invention relates to a cooling pump module and an auxiliary connecting device, which can be used to assist in docking between liquid-cooling pipelines.

### BACKGROUND

For current cooling equipment used in server machines, there is a demand for maintenance or replacement of components while the server machine is operating, i.e., the so-called hot-plug technology. However, in order to prevent coolant leakage during hot plugging, a blocking configuration is currently implemented between the joints of the cooling equipment. To overcome such blocking configuration and reconnect the joints between the cooling equipment, a relatively strong external force is required.

### SUMMARY

In view of the foregoing, how to design an improved solution that enables smoother docking between liquid-cooling pipelines has become a direction of development for those skilled in the art.

According to one aspect of the present invention, an auxiliary connecting device is provided. The auxiliary connecting device includes a tray, a base, and a guide rod. The tray has a first bearing fixed thereon. The base is slidably disposed on the tray. The base has a second bearing fixed thereon. The guide rod is rotatably disposed and passes through the second bearing. When the base slides relative to the tray, the guide rod moves toward the first bearing. When the guide rod moves close to the first bearing, the guide rod is rotatable to engage with the first bearing. When the guide rod rotates in the first bearing, the guide rod pushes against the second bearing to apply a force to the base.

According to another aspect of the present invention, a cooling pump module is provided for supplying a coolant through a first liquid-cooling pipeline into a second liquid-cooling pipeline of an electronic device. The cooling pump module includes a cooling pump and an auxiliary connecting device. The cooling pump has the first liquid-cooling pipeline. The auxiliary connecting device is used to connect the first liquid-cooling pipeline with the second liquid-cooling pipeline. The auxiliary connecting device includes a tray, a base and a guide rod. The tray has a first bearing. The first bearing is disposed on the tray at a side facing the cooling pump. The base is slidably disposed on the tray. One side of the base carries the cooling pump. Another side of the base has a second bearing disposed thereon. The guide rod is rotatably disposed and passes through the second bearing, and engages with the first bearing.

According to yet another aspect of the present invention, a cooling pump module is provided for supplying a coolant to an electronic device. The cooling pump module comprises a cooling pump and an auxiliary connecting device. The auxiliary connecting device is used to connect the cooling pump with a liquid-cooling pipeline of the electronic device. The tray has a first bearing. The first bearing is disposed on the tray at a side facing the cooling pump. The base is slidably disposed on the tray. One side of the base carries the cooling pump. Another side of the base has a second bearing fixed thereon. A space is formed between the base and the tray. The guide rod is disposed in the space between the tray and the base. The guide rod is rotatably disposed and passes through the second bearing, and is rotatable to engage with the first bearing.

The auxiliary connecting device provided in the present invention has designs such as a base and a tray being slidable relative to each other, a guide rod disposed on the bearing of the base being movable and rotatable to engage with the bearing on the tray, and the guide rod being able to push against the second bearing to apply a force to the base when rotating in the bearing on the tray. Through these designs, the auxiliary connecting device of the present invention can facilitate a liquid-cooling pipeline mounted on the base to be easily docked with another liquid-cooling pipeline mounted on the tray, thereby providing a labor-saving effect.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic view of an auxiliary connecting device according to an embodiment of the present invention applied for docking between liquid-cooling pipelines.

FIG. 2 illustrates a schematic view of the auxiliary connecting device according to an embodiment of the present invention.

FIG. 3 illustrates an exploded view of the auxiliary connecting device according to an embodiment of the present invention.

FIGS. 4A, 4B, and 4C illustrate bottom views of operating stages of the auxiliary connecting device according to an embodiment of the present invention.

FIG. 5 illustrates a bottom view of partial components of the auxiliary connecting device according to another embodiment of the present invention.

### DETAILED DESCRIPTION

Detailed descriptions of the embodiments of the specification are disclosed below with reference to the accompanying drawings. Apart from the detailed descriptions provided, any embodiments in which the present invention can be used as well as any substitutions, modifications or equivalent changes of the said embodiments are within the scope of the disclosure, and the descriptions and definitions in the claims shall prevail. In the following detailed description, for purposes of explanation, numerous specific details are set forth in order to provide a thorough understanding of the disclosed embodiments. It will be apparent, however, that one or more embodiments may be practiced without these specific details. Additionally, well-known common steps or components are not described in detail to avoid unnecessarily limiting the present invention. The same or similar elements in the figures are represented by the same or similar symbols.

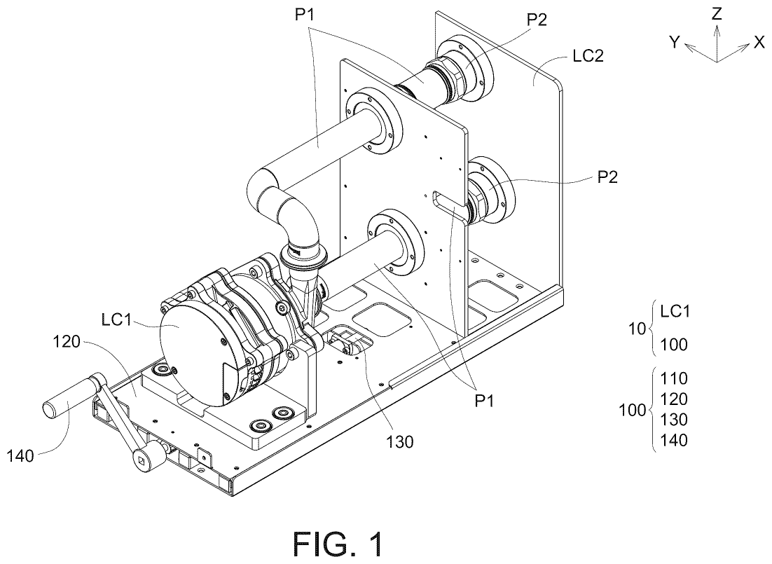

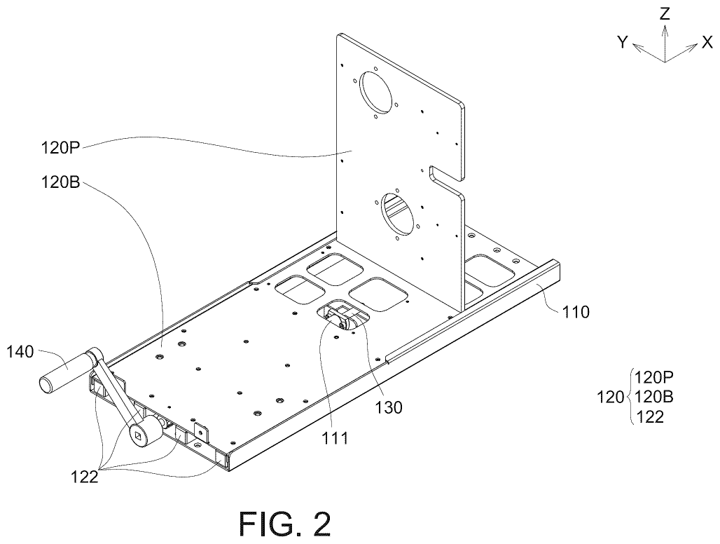

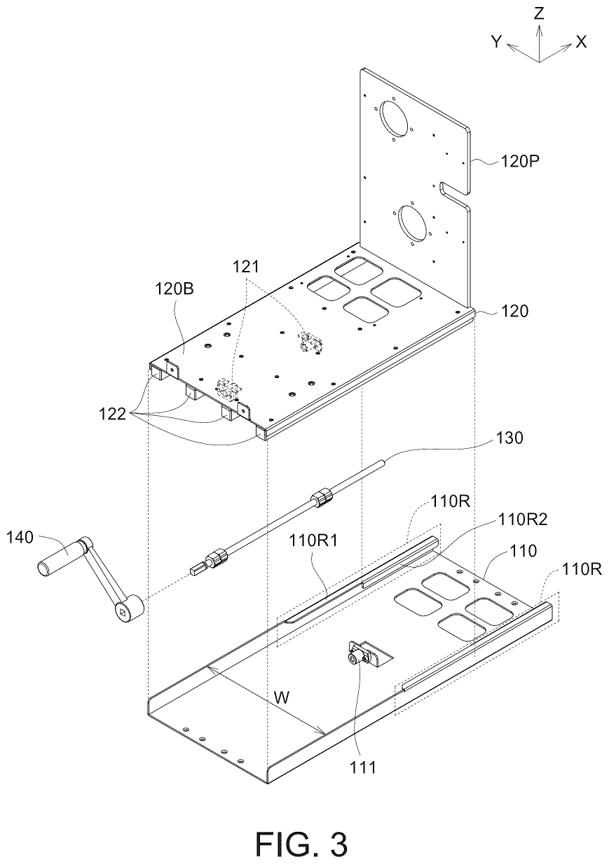

Please refer to FIGS. 1, 2, and 3, FIG. 1 illustrates a schematic view of an auxiliary connecting device 100 according to an embodiment of the present invention applied for docking between a first liquid-cooling pipeline P1 of a first device LC1 and a second liquid-cooling pipeline P2 of a second device LC2. FIG. 2 illustrates a schematic view of the auxiliary connecting device 100, and FIG. 3 illustrates an exploded view of the auxiliary connecting device 100.

The first device LC1 may be, for example, a cooling pump. The second device LC2 may be, for example, an electronic device such as a server machine, is illustrated in FIG. 1, in order to simplify the drawing. The first device LC1 and the auxiliary connecting device 100 may constitute a cooling pump module 10. That is, a cooling pump module 10 according to an embodiment of the present invention may include the first device LC1 and the auxiliary connecting device 100. The cooling pump module 10 may be used to supply a coolant through the first liquid-cooling pipeline P1 of the first device LC1 into the second liquid-cooling pipeline P2 of the second device LC2. Specifically, the first liquid-cooling pipeline P1 and the second liquid-cooling pipeline P2 may respectively include quick connectors. This configuration allows hot plugging while the second device LC2 such as the server machine, remains in operation. Accordingly, maintenance and/or component replacement in the first device LC1, such as a cooling pump, can be performed without interrupting the operation of the second device LC2. To prevent coolant leakage during hot plugging, a rebound design is generally provided in the quick connector, which results in a certain degree of resistance when reconnecting the two connectors. The auxiliary connecting device 100 can be used to assist the quick connection between the first liquid-cooling pipeline P1 of the first device LC1 and the second liquid-cooling pipeline P2 of the second device LC2. That is, the auxiliary connecting device 100 can be used to connect the first liquid-cooling pipeline P1 and the second liquid-cooling pipeline P2 to each other, effectively overcoming the resistance during connector docking and thereby achieving a labor-saving effect.

The auxiliary connecting device 100 may comprise a tray 110, a base 120, a guide rod 130 and a handle 140. Specifically, the base 120 may include a bottom 120B and a standing plate 120P, which may be substantially perpendicular to each other. The first device LC1 may be mounted on the bottom 120B of the base 120, and its first liquid-cooling pipeline P1 may be inserted through and fixed to a corresponding through hole in the standing plate 120P. The second device LC2 may be mounted on one side of the tray 110, or alternatively disposed adjacent to the tray 110. The first liquid-cooling pipeline P1 of the first device LC1 and the second liquid-cooling pipeline P2 of the second device LC2 are aligned on the Y-Z plane, thereby enabling docking along the X-axis direction. The tray 110 may have a first bearing 111 fixed thereon. The first bearing 111 may have internal threads and may be disposed on the tray 110 at a side facing the first device LC1. The base 120 may be slidably disposed on the tray 110, and one side of the base 120 may carry the first device LC1. Specifically, the inlet size W of the tray 110 (see FIG. 3) is equivalent to the bottom 120B, such that the base 120 can be directly placed on the tray 110 from above. The tray 110 may further have two sliding rails 110R, which are configured at a distance inward from the inlet of the tray 110 and respectively correspond to both sides of the bottom 120B of the base 120, such that the bottom 120B can slide along the extending direction of the sliding rails 110R. The sliding rail 110R may further be divided into a first portion 110R1 and a second portion 110R2. As shown in FIG. 3, the first portion 110R1 is a plate-shaped structure extending along the X-Y plane, while the second portion 110R2 is a plate-shaped structure extending along the X-Z plane. That is, the first portion 110R1 and the second portion 110R2 may be substantially perpendicular to each other. The second portion 110R2 may be used to stop the base 120 from further moving in the X-axis direction toward the second liquid-cooling pipeline P2. When the base 120 finally moves along the X-axis direction to the position shown in FIG. 2, the second portion 110R2 of the sliding rail 110R pushes against the base 120 and provides a stopping function. Specifically, the second portion 110R2 of the sliding rail 110R may stop the base 120 by abutting against the bottom 120B of the base 120 and a plurality of supporting rails 122 fixed to the base 120.

The supporting rails 122 fixed to the base 120 are mainly used for supporting the bottom 120B to prevent deformation of the bottom 120B caused by the weight of the first device LC1. Specifically, the supporting rails 122 may be fixed to the bottom 120B of the base 120. In this embodiment, the number of supporting rails 122 is set to four, but the present invention is not limited thereto. The supporting rails 122 may abut against the tray 110, serving as a contact surface when the base 120 slides on the tray 110. The lengths of the plurality of supporting rails 122 may not be identical. In this embodiment, two supporting rails 122 located at the middle of the base 120 have the same length, another two supporting rails 122 located at the outer side of the base 120 have the same length, and the supporting rails 122 located at the middle of the base 120 are shorter than those located at the outer side of the base 120, but the present invention is not limited thereto.

The base 120 has second bearings 121 fixed thereon. In this embodiment, the number of second bearings 121 is set to two, but the present invention is not limited thereto. Opposite to the side of the base 120 carrying the first device LC1, the second bearings 121 are disposed and fixed to the other side of the base 120. Specifically, the second bearings 121 may be fixed to the bottom 120B of the base 120 and located at a side of the bottom 120B facing the tray 110. A space may be formed between the base 120 and the tray 110, and the guide rod 130 may be disposed in this space. The guide rod 130 is rotatably disposed and passes through the second bearings 121. The second bearings 121 may support the rotating guide rod 130 and enable smooth rotation, wherein the second bearings 121 may be unthreaded. The handle 140 is fixed to one end of the guide rod 130 and provides a gripping portion for a user. When the handle 140 is rotated, it drives the guide rod 130 to rotate synchronously. In this embodiment, both the first bearing 111 and the second bearings 121 are selected to be flange bearings, which can provide a locking position, such that the first bearing 111 can be fastened to the tray 110 and the second bearings 121 can be fastened to the base 120.

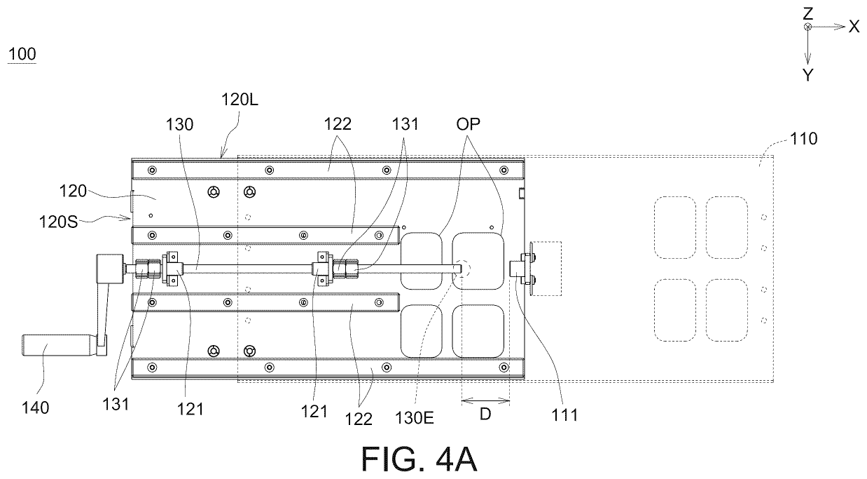

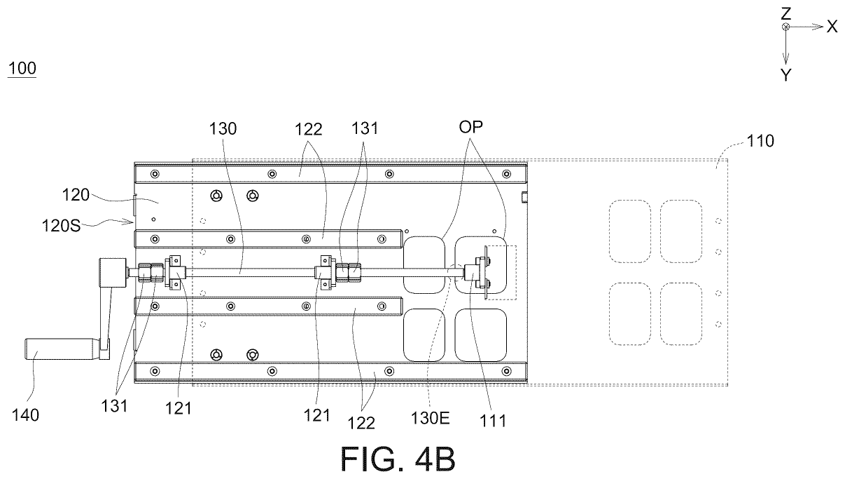

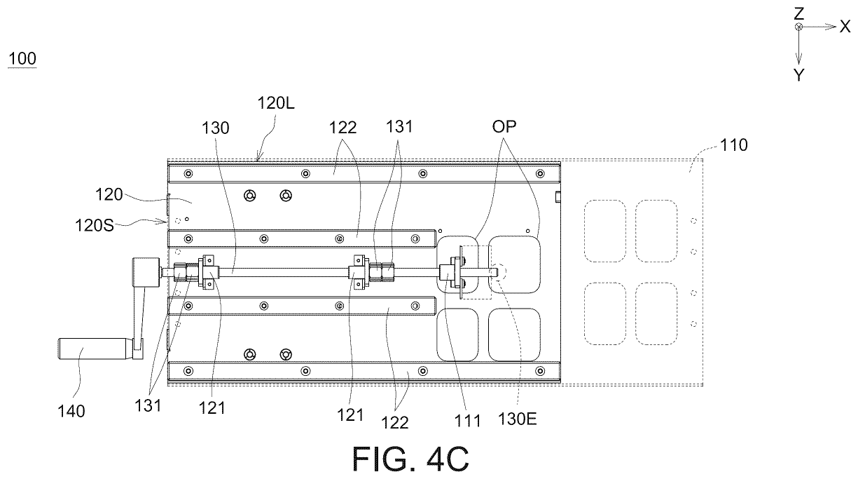

Please further refer to FIGS. 4A, 4B and 4C, FIG. 4A illustrates a bottom view of the auxiliary connecting device 100 in a first operating stage, FIG. 4B illustrates a bottom view of the auxiliary connecting device 100 in a second operating stage, and FIG. 4C illustrates a bottom view of the auxiliary connecting device 100 in a third operating stage.

In the first operating stage of the auxiliary connecting device 100 as shown in FIG. 4A, the first liquid-cooling pipelines P1 of the first device LC1 and the second liquid-cooling pipelines P2 of the second device LC2 are not yet docked. Correspondingly, an end portion 130E of the guide rod 130 is in an exposed state, and the end portion 130E is separated from the first bearing 111 on the tray 110 by a distance D, which is substantially the same as the distance between the first liquid-cooling pipelines P1 of the first device LC1 and the second liquid-cooling pipelines P2 of the second device LC2. In addition, the guide rod 130 may be disposed between two of the supporting rails 122 located in the middle of the base 120. These two supporting rails 122 form an accommodating height along the Z-axis, which can prevent interference between the guide rod 130 and the tray 110 during subsequent operation. The base 120 may slide relative to the tray 110. For example, a user may directly apply a pushing force along the X-axis to a short side 120S of the base 120, or apply a pushing force along the X-axis to the handle 140 to indirectly drive the base 120, so as to make the base 120 slide relative to the tray 110.

When the base 120 slides relative to the tray 110, the guide rod 130 may move toward the first bearing 111 on the tray 110 to shorten the distance D between the end portion 130E and the first bearing 111. Specifically, since the guide rod 130 is connected to the second bearings 121 on the base 120, the second bearings 121 may drive the guide rod 130 to approach the first bearing 111 along the X-axis. In the second operating stage of the auxiliary connecting device 100 as shown in FIG. 4B, the guide rod 130 gradually moves close to the first bearing 111 until they come into contact. Correspondingly, at this time, the first liquid-cooling pipeline P1 of the first device LC1 and the second liquid-cooling pipeline P2 of the second device LC2 also come into contact but have not yet been completely docked.

When the guide rod 130 moves close to the first bearing 111 on the tray 110, the guide rod 130 may be rotatable to engage with the first bearing 111. Specifically, by rotating the handle 140 about the X-axis (e.g., in a clockwise direction), the guide rod 130 can be driven to rotate. That is, when the guide rod 130 moves close to the first bearing 111 along the X-axis, the guide rod 130 can be driven by the handle 140 to rotatably engage with the first bearing 111. During the third operating stage of the auxiliary connecting device 100 shown in FIG. 4C, the guide rod 130 engages and extends through the first bearing 111, such that the guide rod 130 can continue to rotate in the first bearing 111. When the guide rod 130 rotates in the first bearing 111, the guide rod 130 can push against the second bearing 121 to apply a force to the base 120. As described above, the hole of the first bearing 111 may be designed with an internal thread, and a shaft surface of the end portion 130E of the guide rod 130 corresponding to the first bearing 111 may be designed with an external thread. That is, when the guide rod 130 moves close to the first bearing 111, the guide rod 130 can be rotated such that the external thread of the guide rod 130 threadedly engages with the internal thread of the first bearing 111. Through the threaded engagement therebetween, a further labor-saving effect can be achieved.

Specifically, the guide rod 130 may include pushing structures 131 fixed thereto. For example, the pushing structure 131 may be implemented as a nut. In this embodiment, the number of nuts serving as the pushing structure 131 is set to four, two of which correspond to the left-side second bearing 121, and the other two correspond to the right-side second bearing 121, but the invention is not limited thereto. That is, one or more nuts may be arranged on the guide rod 130. When the guide rod 130 rotates within the first bearing 111 of the tray 110, the pushing structures 131 may push against the second bearing 121 to apply a force to the base 120. In this embodiment, as shown in FIG. 4C, when the two pushing structures 131 adjacent to the left-side second bearing 121 engage with the first bearing 111 along with the guide rod 130, they push the left-side second bearing 121 rightward along the X-axis. Since the second bearing 121 is fixed to the base 120, the force applied by the pushing structures 131 is transmitted to the base 120 to drive the base 120 to further move relative to the tray 110. Accordingly, the first liquid-cooling pipeline P1 of the first device LC1 mounted on the base 120 is further moved via the pushing of the base 120, thereby providing a sufficient force to overcome the resistance present during docking, and thus completing docking with the second liquid-cooling pipeline P2 of the second device LC2 mounted on the tray 110.

Conversely, when the handle 140 is rotated about the X-axis in the opposite direction (e.g., counterclockwise) to drive the guide rod 130, the guide rod 130 may rotate in the first bearing 111 and gradually disengage from the first bearing 111. For example, when the hole of the first bearing 111 is designed with an internal thread and a shaft surface of the end portion 130E of the guide rod 130 is designed with an external thread, the surface threads of the guide rod 130 may gradually unthread from the threaded hole of the first bearing 111 as the handle 140 is rotated counterclockwise. This process continues until the guide rod 130 and the first bearing 111 are separated by a distance D as shown in FIG. 4A. That is, the disengagement state of the guide rod 130 from the first bearing 111 may proceed in reverse order according to FIG. 4C, FIG. 4B, and FIG. 4A. In addition, if the nut used as the pushing structure 131 has threads, the guide rod must include corresponding threads for engagement. Such a design allows for more flexible installation and removal between the nut and the guide rod, thereby facilitating maintenance. However, the nut used as the pushing structure 131 may alternatively be unthreaded, in which case the nut needs to be welded to the guide rod to prevent relative movement therebetween.

In addition, as shown in FIGS. 4A, 4B and 4C, the base 120 may have a long side 120L and a short side 120S, wherein the guide rod 130 may be disposed at a central position of the short side 120S of the base 120. In this way, the force generated when the guide rod 130 is driven by the handle 140 to rotate and engage with the first bearing 111 can be more evenly distributed, thereby preventing situations where the base 120 cannot be pushed due to the weight of the cooling pump, and further achieving a labor-saving effect. The disclosure utilizes the space between the tray 110 and the base 120 to design a labor-saving structure. The space above the tray 110 can be fully reserved for the cooling pump, which not only effectively saves space, but also provides greater design flexibility for the cooling pump and its surrounding pipelines. The base 120B may further be provided with openings OP to expose the guide rod 130 and the first bearing 111, so as to allow observation of their engagement status.

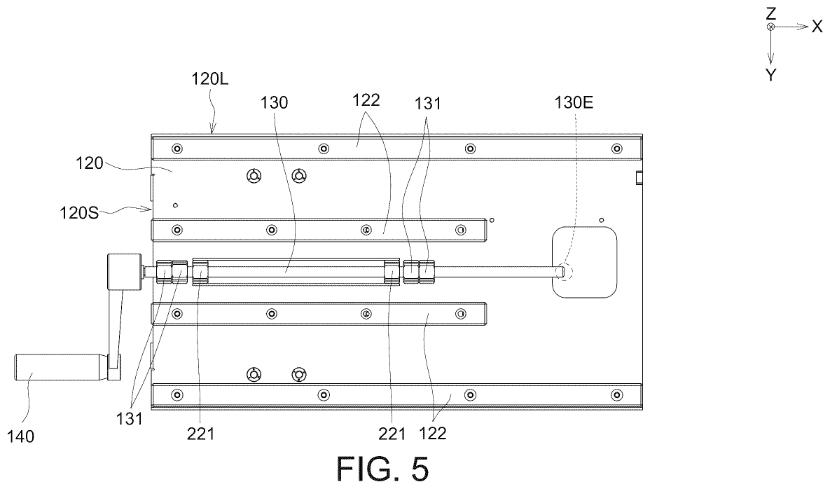

Please further refer to FIG. 5, which illustrates a bottom view of the combination of the base 120, the guide rod 130 and the handle 140 of another embodiment of the auxiliary connecting device 100 of the present invention.

In the embodiment shown in FIG. 5, the auxiliary connecting device 100 may adopt the general implementation details described above, which will not be redundantly described herein. Only the variations are explained in this embodiment. In this embodiment, the foregoing second bearings 121 are replaced with the second bearings 221, such that the guide rod 130 is disposed in the second bearings 221. Specifically, the second bearing 221 is implemented as a nut, which may be welded to the base 120 to be fixed to the side of the base 120 facing the tray 110. Both the second bearings 221 and the pushing structures 131 are nuts, but the pushing structures 131 are nuts fixed to the guide rod 130, whereas the second bearings 221 are nuts movable relative to the guide rod 130, such that the guide rod 130 is rotatably disposed through the second bearings 221.

From the present invention, the auxiliary connecting device in this invention includes the base and the tray that are slidably disposed relative to each other; the guide rod arranged on the base is movable and rotatable to engage with the bearing on the tray. Therefore, when the guide rod rotates within the bearing on the tray, it can push against the second bearings to apply a force to the base. The auxiliary connecting device of the present invention can utilize such a design to easily push the liquid-cooling pipelines mounted on the base to dock with other liquid-cooling pipelines mounted on the tray, thereby providing a labor-saving effect.

It will be apparent to those skilled in the art that various modifications and variations can be made to the disclosed embodiments. It is intended that the specification and examples be considered as exemplars only, with a true scope of the disclosure being indicated by the following claims and their equivalents.

What is claimed is:

1. An auxiliary connecting device, comprising:
a tray having a first bearing fixed thereto;
a base slidably disposed on the tray and having a second bearing fixed thereto; and
a guide rod rotatably disposed and extending through the second bearing;
wherein, when the base slides relative to the tray, the guide rod moves toward the first bearing; when the guide rod moves close to the first bearing, the guide rod is rotatable to engage with the first bearing; and when the guide rod rotates in the first bearing, the guide rod pushes against the second bearing to apply a force to the base.

2. The auxiliary connecting device of claim 1, further comprising:
a handle fixed to one end of the guide rod, wherein when the guide rod moves close to the first bearing, the guide rod is driven by the handle to rotatably engage with the first bearing.

3. The auxiliary connecting device of claim 1, wherein the guide rod has a pushing structure fixed thereto, and when the guide rod rotates in the first bearing, the pushing structure pushes against the second bearing to apply a force to the base.

4. The auxiliary connecting device of claim 3, wherein the pushing structure is a nut, and one or more nuts are disposed on the guide rod.

5. The auxiliary connecting device of claim 1, wherein the first bearing has an internal thread, and one end of the guide rod corresponding to the first bearing has an external thread, such that when the guide rod moves close to the first bearing, the guide rod is rotatable to engage the external thread of the guide rod with the internal thread of the first bearing.

6. The auxiliary connecting device of claim 1, wherein the first bearing is a flange bearing fastened to the tray.

7. The auxiliary connecting device of claim 1, wherein the second bearing is a flange bearing fastened to the base.

8. The auxiliary connecting device of claim 1, wherein the second bearing is a nut welded to the base.

9. The auxiliary connecting device of claim 1, wherein the base has a long side and a short side, and the guide rod is located at a central position of the short side.

10. The auxiliary connecting device of claim 1, wherein the base has a supporting rail fixed thereto, and the supporting rail abuts against the tray.

11. A cooling pump module for providing a coolant through a first liquid-cooling pipeline to a second liquid-cooling pipeline of an electronic device, comprising:
a cooling pump having the first liquid-cooling pipeline; and
an auxiliary connecting device for connecting the first liquid-cooling pipeline with the second liquid-cooling pipeline, comprising:
a tray having a first bearing disposed on the tray at a side facing the cooling pump;
a base slidably disposed on the tray, one side of the base carrying the cooling pump, and another side of the base having a second bearing disposed thereon; and
a guide rod rotatably disposed and extending through the second bearing and being rotatable to engage with the first bearing.

12. The cooling pump module of claim 11, wherein the auxiliary connecting device further comprises:
a handle fixed to one end of the guide rod, wherein when the guide rod moves close to the first bearing, the guide rod is driven by the handle to rotatably engage with the first bearing.

13. The cooling pump module of claim 11, wherein the guide rod has a pushing structure fixed thereto, and when the guide rod rotates in the first bearing, the pushing structure pushes against the second bearing to apply a force to the base.

14. The cooling pump module of claim 11, wherein the first bearing has an internal thread, and one end of the guide rod corresponding to the first bearing has an external thread, such that when the guide rod moves close to the first bearing, the guide rod is rotatable to engage the external thread of the guide rod with the internal thread of the first bearing.

15. The cooling pump module of claim 11, wherein the base has a supporting rail fixed thereto, and the supporting rail abuts against the tray.

16. A cooling pump module for providing a coolant to an electronic device, comprising:
a cooling pump; and
an auxiliary connecting device for connecting the cooling pump with a liquid-cooling pipeline of the electronic device, comprising:
a tray having a first bearing disposed on the tray at a side facing the cooling pump;
a base slidably disposed on the tray, one side of the base carrying the cooling pump, another side of the base having a second bearing fixed thereto, and a space being formed between the base and the tray; and
a guide rod disposed in the space between the tray and the base, the guide rod being rotatably disposed and extending through the second bearing and being rotatable to engage with the first bearing.

17. The cooling pump module of claim 16, wherein the auxiliary connecting device further comprises:
a handle fixed to one end of the guide rod, wherein when the guide rod moves close to the first bearing, the guide rod is driven by the handle to rotatably engage with the first bearing.

18. The cooling pump module of claim 16, wherein the guide rod has a pushing structure fixed thereto, and when the guide rod rotates in the first bearing, the pushing structure pushes against the second bearing to apply a force to the base.

19. The cooling pump module of claim 16, wherein the first bearing has an internal thread, and one end of the guide rod corresponding to the first bearing has an external thread, such that when the guide rod moves close to the first bearing, the guide rod is rotatable to engage the external thread of the guide rod with the internal thread of the first bearing.

20. The cooling pump module of claim 16, wherein the base has a supporting rail fixed thereto, the supporting rail abuts against the tray.
